(19) United States
(12) Patent Application Publication
(10) Pub. No.: US 2024/0087985 A1
(43) Pub. Date: Mar. 14, 2024

(54) DUAL-SIDED COOLING JACKET

(71) Applicant: US Hybrid Corporation, Torrance, CA (US)

(72) Inventors: Alex Nguyen, Fullerton, CA (US); Gordon Abas Goodarzi, Rolling Hills, CA (US)

(21) Appl. No.: 17/944,945

(22) Filed: Sep. 14, 2022

(51) Int. Cl. H01L 23/44; H01L 23/473

(52) U.S. Cl. CPC H01L 23/44; H01L 23/473

(57) ABSTRACT

Disclosed is a dual-sided cooling jacket configured to receive and cool devices on both sides of the cooling jacket. The cooling jacket may include a main fluid chamber that receives and outputs fluid from an inlet and an outlet, respectively. A first plate and a second plate may be joined to form the cooling jacket with the main fluid chamber therebetween. The first plate may include first threaded members that allow one or more devices to be mounted to the first plate. The second plate may include second threaded members that allow devices to be mounted to the second plate. The cooling jacket may include a siphon line to prevent accumulation of air bubbles within the main fluid chamber. Other examples may be described and claimed.

### BACKGROUND

Conventional cooling systems may include a cooling jacket that is configured to mount devices to one side of the cooling jacket. Sometimes, two one-sided cooling jackets are positioned back-to-back to mount devices on two exterior sides of the combined one-sided cooling jackets. This multipiece approach can be labor intensive and introduces potential leak points at each sealing plate.

### BRIEF SUMMARY

Disclosed is a fluid transfer system having a dual-sided cooling jacket for mounting devices on both sides. The dual-sided cooling jacket may include a main fluid chamber that receives and outputs fluid from an inlet and an outlet. A first plate and a second plate may each account for approximately half of the width of the main fluid chamber. The first plate may include first pins that the fluid flows around in the main fluid chamber. The first plate may include first threaded pins that are bored and threaded so that devices to be cooled can be mounted on the first plate by way of threaded fasteners and the threaded pins. The second plate may include second pins that the fluid flows around in the main fluid chamber. The second plate may include second threaded pins that are bored and threaded so that devices to be cooled can be mounted on the second plate by way of the threaded fasteners and the second threaded pins.

The features, functions, and advantages that have been discussed above or will be discussed below can be achieved independently in various embodiments, or may be combined in yet other embodiments, further details of which can be seen with reference to the following description and drawings.

### BRIEF DESCRIPTION OF THE DRAWINGS

The detailed description is described with reference to the accompanying figures. In the figures, the left-most digit(s) of a reference number identifies the figure in which the reference number first appears. The use of the same reference number in different figures indicates similar or identical items.

FIG. 1 is an illustration of a block diagram of a vehicle that uses the various embodiments of a fluid transfer system having a cooling jacket for mounting devices on both sides.

FIG. 2 is an illustration of a block diagram of a fluid transfer system that uses the various embodiments of a cooling jacket described in FIG. 1.

FIG. 3 is an illustration of a bottom, front, and left-side elevational view of an exemplary cooling jacket, such as that illustrated in FIG. 1, where devices can be mounted on both sides of the cooling jacket in accordance with various embodiments.

FIG. 4 is an illustration of a bottom, front, and left-side elevational view of an exemplary cooling jacket, such as that illustrated in FIG. 1, showing a main fluid chamber, fins/pins, and threaded fins/pins at a body structure in accordance with various embodiments.

FIG. 5 is an illustration of a bottom, rear, and right-side elevational view of an exemplary cooling jacket, such as that illustrated in FIG. 1, showing a main fluid chamber, fins/pins, and threaded fins/pins at a body structure in accordance with various embodiments.

FIG. 6 is an illustration of a front view of an exemplary cooling jacket, such as that illustrated in FIG. 5, showing a main fluid chamber at a body structure of the cooling jacket in accordance with various embodiments.

FIG. 7 is an illustration of a cross-sectional view of the main fluid chamber along line A-A of a portion of the top section of the main fluid chamber in accordance with various embodiments.

FIG. 8 is an illustration of another cross-sectional view of the main fluid chamber along lines A-A of a portion of the top section of the main fluid chamber 210 in accordance with various embodiments.

FIG. 9 is an illustration of cross-sectional view of the main fluid chamber along lines A-A of a portion of the top section of the main fluid chamber in accordance with various embodiments.

FIG. 10 is an illustration of a flow diagram illustrating an exemplary process for using the exemplary embodiments of the cooling jacket shown in the preceding figures.

### DETAILED DESCRIPTION

The present disclosure is directed to a fluid transfer system that allows for high density packaging of power electronics while providing equivalent parallel cooling for devices that are mounted on both the top side and the bottom side of a liquid cold plate of a cooling jacket. This can be best realized by integrating the cooling solution with highly paralleled multi-channel power electronics modules and by utilizing both planar faces of a liquid cooling plate to optimize the use of space. The present disclosure can reduce the number of cooling plate assemblies required for a given application by at least in half and reduce the plumbing requirements by at least half. The two cooling plates share a single cooling loop, rather than simply mounting two cold plates back-to-back, thereby simplifying internal plumbing and reducing potential leak points.

The two cooling plates can each have cooling and flow paths formed in them. Each half can be designed so that it can accommodate the arrangement of the respective heat dissipating devices attached to it while also having a cooling path that can match its counterpart so that the bulk of the flow can be directed in the same path for both halves and so that only one inlet and one outlet can serve both halves.

Having pin fin arrays on each half can ensure that the threaded mounting holes for the devices can be completely isolated from the fluid in the cooling jacket. This also allows for smaller pin fin geometry and tighter tolerances around pins/fins which allows for improved flow through the device.

Having pin fin arrays and mounting features on each half can allow equal depths for the flow channel which in turn provides an equivalent thermal resistance path in the Z-axis from the device to a fluid layer.

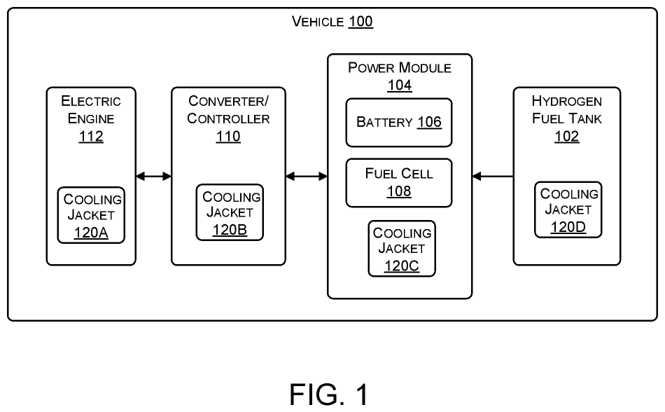

Many specific details of certain embodiments are set forth in the following description and in FIGS. 1-10 to provide a thorough understanding of such embodiments. The present disclosure may have additional embodiments or may be practiced without one or more of the details described below.

Referring more particularly to the drawings, embodiments of this disclosure may be described in the context of a vehicle 100 having a cooling jacket 120, such as that shown in FIG. 1. The vehicle 100 can include, but is not limited to, the following components: a hydrogen fuel tank 102, a power module 104, a converter/controller 110, and an electric engine 112, each of which can be implemented with a cooling jacket 120A-D, respectively. The cooling jacket 120 is further shown and explained in the succeeding figures.

The hydrogen fuel tank 102 supplies hydrogen to a fuel cell 108 that generates electricity. The electric engine 112 can be powered by a battery 106 and/or the fuel cell 108 via the converter/controller 110. The battery 106 can be recharged by the generated electricity from the fuel cell 108. It should be noted that the vehicle 100 is shown as a hydrogen fuel cell vehicle, but the vehicle 100 can also be a battery electric vehicle, a hybrid electric vehicle, a plug-in hybrid electric vehicle, or other type of vehicle.

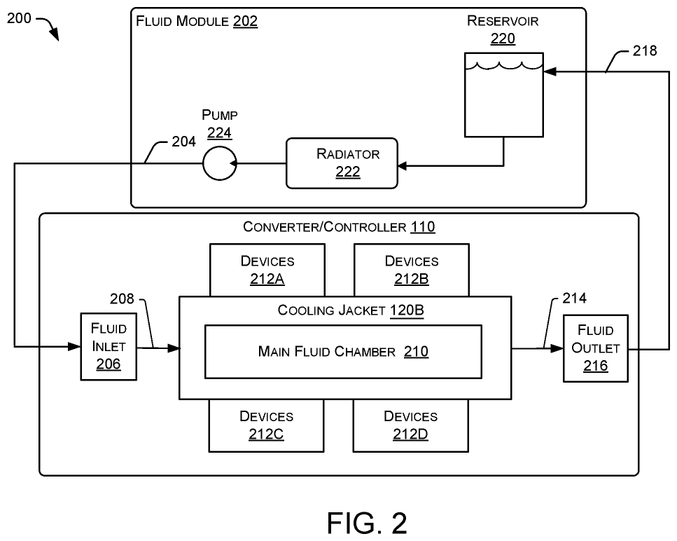

FIG. 2 is an illustration of a block diagram of the fluid transfer system 200 having the cooling jacket 120B described in FIG. 1. The fluid transfer system 200 may include a fluid module 202 that may include a pump 224, a radiator 222, and a reservoir 220. The pump 224 may circulate the fluid through the fluid transfer system 200. The reservoir 220 may contain a volume of fluid that is circulated back from the pump 224. The radiator 222 may intake the fluid from the reservoir 220 and transfer heat from the fluid to ambient air. The radiator may include a fan (not shown) mounted thereto and configured to provide forced convection. The fluid may exit from the radiator 222 and flow to an inlet of the pump 224. In other examples, the radiator 222 may be positioned at other suitable locations in the fluid module 202, such as before the reservoir.

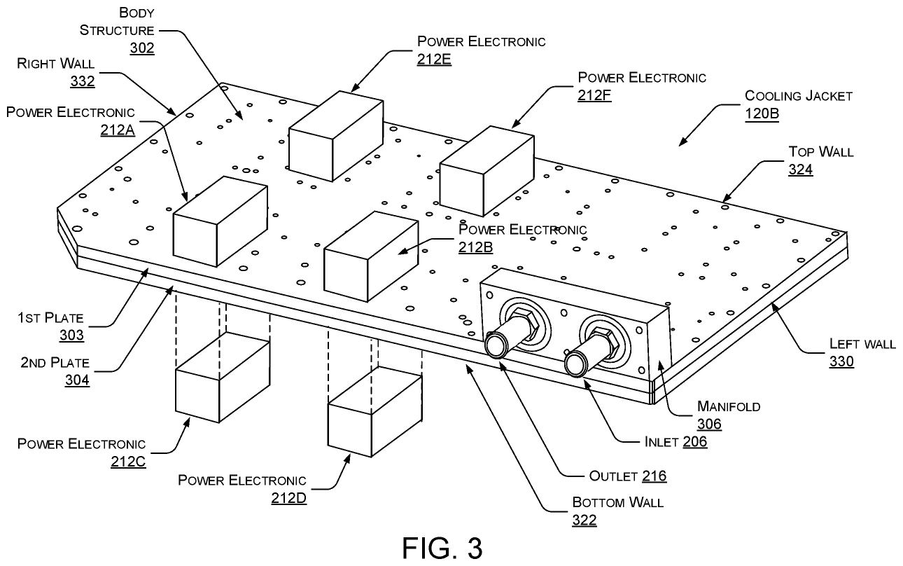

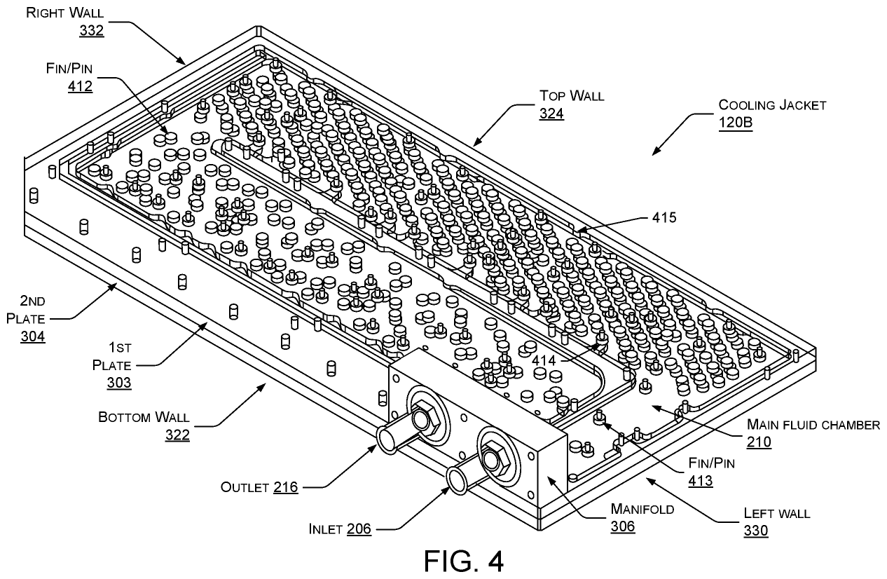

The fluid at line 204 from the pump 224 may enter the converter/controller 110 via a fluid inlet 206 that introduces the fluid at line 208 to a cooling jacket 120B for mounting devices on both sides of the cooling jacket 120B. The cooling jacket 120B may include a main fluid chamber 210 for the fluid to pass therethrough. The fluid may exit from the cooling jacket 120B at line 214 through a fluid outlet 216, which delivers the fluid at line 218 to the reservoir 220. The cooling jacket 120 can be made of, but is not limited to, cast iron, alloy and structural steel, or aluminum alloys. The cooling jacket 120B may include two (2) cold plates 303, 304 (FIG. 3) with both sides having complete fin/pin arrays 412, 413 (FIG. 4), the cold plates 303, 304 of which can be screwed, bonded, and/or welded together where they meet. Both plates 303, 304 can be designed to accommodate and interface with the power electronics or other heat generating components 212A-D, as shown in FIG. 3. In the vehicle example of FIG. 1, other heat generating components can include a fuel cell 108, a battery 106, an electric engine 112, or a hydrogen fuel tank 102. The cooling jacket 120 is further shown and described in the succeeding figures.

FIG. 3 is an illustration of a bottom, front, and left-side elevational view of an exemplary dual-sided cooling jacket 120, such as that illustrated in FIG. 1, where devices can be mounted on both sides of the cooling jacket 120 in accordance with various embodiments. The cooling jacket 120 may include a body structure 302 having a first plate 303 joined to a second plate 304. The first plate 303 can have a first exterior mounting surface 325, and the second plate 304 can have a second exterior mounting surface 326. Devices to be cooled (e.g., 212A, B, E, F) can be mounted to the first exterior mounting surface 325. Devices to be cooled (e.g., 212C, D) can be mounted to the second exterior mounting surface 326. The body structure 302 may include a bottom wall 322, top wall 324, left wall 330, and right wall 332. The body structure 302 may include an inlet 206 and an outlet 216 that are positioned at the bottom wall 322 of the body structure 302. The inlet 206 and the outlet 216 may be coupled to the body structure 302 by way of a manifold 306. The inlet 206 and the outlet 216 may be positioned at or near a corner of the bottom wall 322 and the left wall 330. The inlet 206 and the outlet 216 may be positioned on top of the first plate 303. It should be noted that the inlet 206 and the outlet 216 can be directly coupled to either the first plate 303 or the second plate 304 without the manifold 306.

FIG. 4 is an illustration of a bottom, front, and left-side elevational view of an exemplary cooling jacket 120, such as that illustrated in FIG. 1. In the embodiments shown, the first plate 303 and second plate 304 may be represented as transparent members to reveal internal details of the dual-sided cooling jacket 120. In practice, the first plate 303 and second plate 304 may be made of one or materials that are not transparent, such as aluminum, copper, or other material with suitable heat transfer properties. The cooling jacket 120 may include a main fluid chamber 210. The cooling jacket 120 may include fins/pins 412 located within the main fluid chamber 210. The fins/pins 413 may improve mixing of the fluid and promote turbulent flow within the fluid chamber 210 and thereby enhance heat transfer from the first and second plates 303, 304 to the circulating fluid. The cooling jacket 120 may include a main fluid chamber 210 with threaded fins/pins 413 extending into the main fluid chamber from body structure 302 in accordance with various embodiments. Like features are labeled with the same reference numbers, such as the fluid inlet 206, fluid outlet 216, body structure 302, bottom wall 322, top wall 324, left wall 330, right wall 332, first plate 303, second plate 304, and manifold 306. The cooling jacket 120 of FIG. 4 may be configured to include the main fluid chamber 210, fins/pins 412, threaded fins/pins 413, threaded protrusions 414 and protrusions 415, which are further described in the succeeding figures. It should be noted that although the figures may show only cylindrical pins, one skilled in the art can appreciate that finned surfaces (e.g., formed by skiving) can also be designed to replace the pins or in combination with the pins.

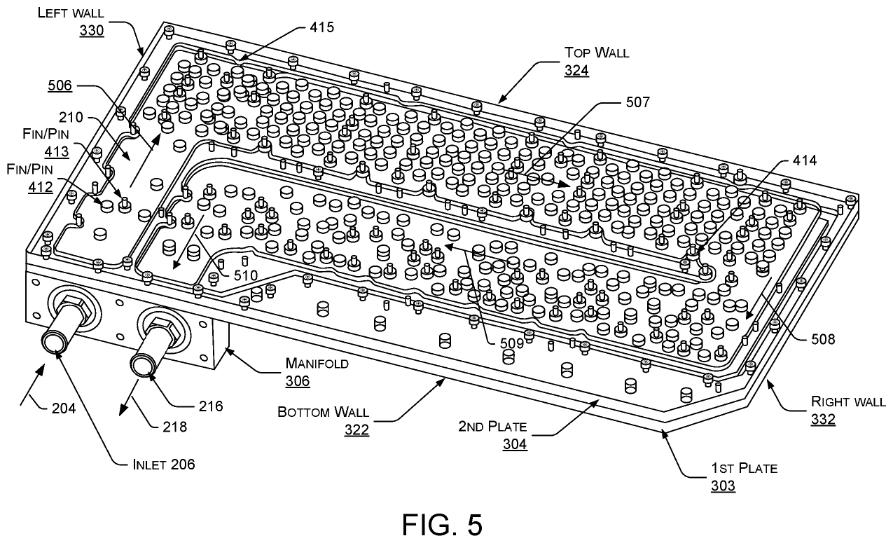

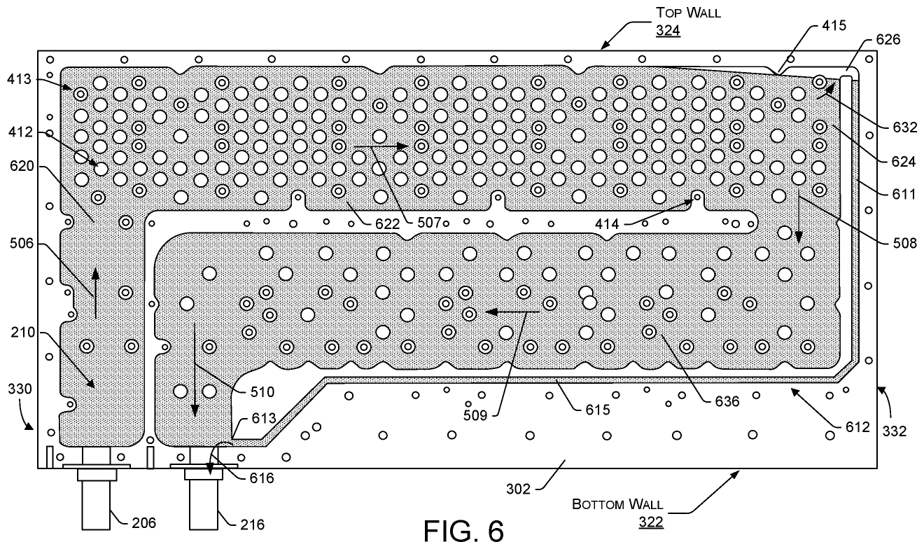

FIG. 5 is an illustration of a bottom, rear, and right-side elevational view of an exemplary dual-sided cooling jacket 120, such as that illustrated in FIG. 1, showing a main fluid chamber 210, fins/pins 412, and threaded fins/pins 413 at a body structure 302 in accordance with various embodiments. Like features are labeled with the same reference numbers, such as the fluid inlet 206, fluid outlet 216, body structure 302, bottom wall 322, top wall 324, left wall 330, right wall 332, first plate 303, second plate 304, manifold 306, main fluid chamber 210, fins/pins 412, threaded fins/pins 413, threaded protrusions 414 and the protrusions 415. Directional arrows 204, 506, 507, 508, 509, 510, 218 show the direction of the fluid entering the main fluid chamber 210 at the inlet 206, flowing around the fins/pins 412, threaded fins/pins 413, threaded protrusions 414, and protrusions 415, and exiting the main fluid chamber 210 at the outlet 216. The main fluid chamber 210 is further described in FIG. 6.

FIG. 6 is an illustration of a front view of an exemplary dual-sided cooling jacket 120, such as that illustrated in FIG. 5, showing a main fluid chamber 210 at a body structure 302 of the cooling jacket 120 in accordance with various embodiments. Like features are labeled with the same reference numbers, such as the fluid inlet 206, fluid outlet 216, body structure 302, bottom wall 322, top wall 324, left wall 330, right wall 332, main fluid chamber 210, fins/pins 412, threaded fins/pins 413, threaded protrusions 414 and the protrusions 415. The cooling jacket 120 of FIG. 4 is configured to further include a siphon line 612 that can draw trapped air bubbles out of the main fluid chamber 210.

In this example, the main fluid chamber 210 may have a left section 620 that is fluidly connected to the inlet 206 (FIG. 3), a top section 622 that is positioned at or near the top wall of the main fluid chamber 210, a right section 624 that is fluidly connected to a priming inlet 626 of the siphon line 612, and a bottom section 636 that is positioned at or near the bottom wall 322 of the body structure 302. The siphon line 612 may include a right section 611 that is positioned at or near the right section 624 of the main fluid chamber 210 and a bottom section 615 that is positioned at or near the bottom section 636 of the main fluid chamber 210 and fluidly connected to the outlet 216.

The fluid/air bubbles enter the fluid inlet 206 flowing into the left section 620 of the main fluid chamber 210 at line 506. The fluid/air bubbles travel up the left section 620, across the top section 622 at line 507, down the right section 624 at line 508, across the bottom section 636 at line 509, out the bottom section 636 at line 510 and out the outlet 216. The top right corner of the top section 622/right section 624 is coupled to the priming inlet 626, where the fluid/air bubbles enter and travel towards a siphon outlet 613 and outlet 216. The protrusions 415 can trap the fluid/air bubbles between the priming inlet 626 and the protrusion 415, and the fluid/air bubbles can be drawn into the priming inlet 626 at line 632 and out the siphon outlet 613 at line 616. The fluid (typically not the air bubbles) travels down through the right section 624 of the main fluid chamber 210 at line 508.

The siphon line 612 can be narrower (i.e., have a smaller cross-sectional area) than the main fluid chamber 210. The priming inlet 626 allows the air bubbles that would normally be trapped at the top section 622 of the main fluid chamber 210 to be drawn out at line 632 through an enclosed high velocity straw-like pathway of the siphon line 612. The direct connection of the siphon line 612 to the fluid outlet 216 and the narrow-enclosed pathway of the siphon line 612 can create a higher draw than the main fluid chamber 210 which flows at a much slower relative velocity due to difference in cross-sectional area between the flow paths. Positioning the priming inlet 626 at the top right corner of the main fluid chamber 210 can allow the air bubbles to naturally collect into the priming inlet 626 and be carried away in the right section 611 of the siphon line 612 having a smaller cross-sectional area than the right section 624 of the main fluid chamber 210. The siphon line 612 may prevent air bubbles from accumulating over time and forming a larger air pocket that adversely impacts heat transfer performance of the cooling jacket 120.

In this example, the siphon line 612 is positioned along the outer peripheral of the main fluid chamber 210. In another embodiment, the siphon line 612 can be positioned in front or back of the main fluid chamber 210.

The density of fin/pin arrays 412, 413 in the main fluid chamber 120 may decrease between the inlet 206 and the outlet 216. This configuration may allow for volume expansion of the fluid as it absorbs heat as it travels along a flow path through the main fluid chamber 120. In the example of FIG. 6, a quantity of the plurality of first pins 412 in the top section 622 may be greater than a quantity of the plurality of first pins in the bottom section 636. Similarly, a quantity of the plurality of second pins 413 in the top section 622 may be greater than a quantity of the plurality of second pins in the bottom section 636.

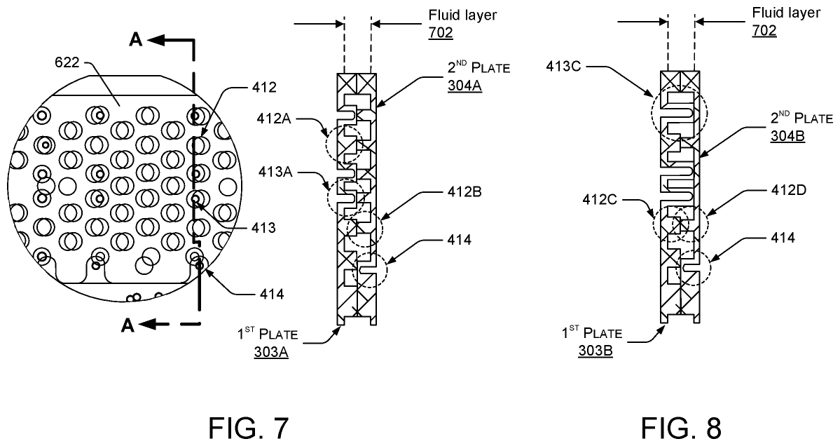

FIG. 7 is an illustration of a cross-sectional view of the main fluid chamber 210 taken along line A-A of a portion of the top section 622 of the main fluid chamber 210 in accordance with various embodiments. Like features are labeled with the same reference numbers, such as the top section 622 of the main fluid chamber 210, first plate 303, second plate 304, fins/pins 412, threaded fins/pins 413, and threaded protrusions 414. FIG. 7 provides a more detailed view of the fins/pins 412, threaded fins/pins 413, and threaded protrusions 414.

In this example, the main fluid chamber 210 has a fluid layer 702 that can be described as the width 702 of the main fluid chamber 210. The first plate 303A may be about half of the width 702 of the main fluid chamber 210. The first plate 303A may include first pins 412A that the fluid flows around in the main fluid chamber. The first plate 303A may include first threaded pins 413A that are bored and threaded so that one or more devices can be mounted on the first plate by way of threaded fasteners and the threaded pins. In other examples, the threaded pins 413A can be replaced by any other suitable threaded member, such as a threaded hole or threaded stud.

The second plate 304A may account for the remaining width 702 of the main fluid chamber 210. The second plate 304A may include second pins 412B and threaded protrusions 414 that the fluid flows around in the main fluid chamber 210. The second plate 304A can include second threaded pins (not shown) that are bored and threaded so that the one or more devices can be mounted on the second plate by way of the threaded fasteners and the second threaded pins. The first threaded pins 413A and the second threaded pins can be bored and threaded before piercing through an inner wall of the first threaded pins 413A and the seconded threaded pins.

The first threaded pins 413A and the second pins 412B may be aligned together, extending the entire width 702 of the main fluid chamber 210. Although not shown, the second threaded pins and the first pins 412A can also be aligned together, extending the entire width 702 of the main fluid chamber 210. The first threaded pins 413A and the second threaded pins can be staggered so that the devices 212 can be mounted on the first plate 303A and the second plate 304A opposite and misaligned from each other.

FIG. 8 is an illustration of another cross-sectional view of the main fluid chamber 210 along lines A-A of a portion of the top section 622 of the main fluid chamber 210 in accordance with various embodiments. Like features are labeled with the same reference numbers, such as the top section 622 of the main fluid chamber 210, first plate 303, second plate 304, fins/pins 412, threaded fins/pins 413, and threaded protrusions 414. The main fluid chamber 210 of FIG. 7 provides another embodiment of the first threaded fins/pins 413C that extend the entire width 702 of the main fluid chamber 210. Although not shown, the second threaded pins can also extend the entire width 702 of the main fluid chamber 210. The first threaded pins 413C and the second threaded pins can be staggered so that the devices 212 can be mounted on the first plate 303B and the second plate 304B opposite and misaligned from each other.

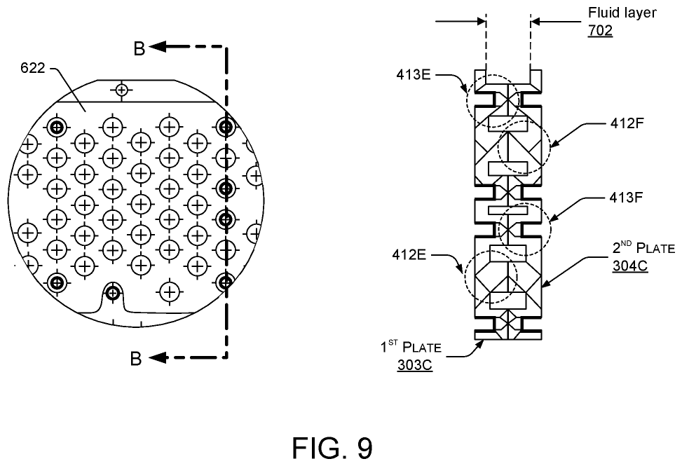

FIG. 9 is an illustration of a cross-sectional view of the main fluid chamber 210 along line B-B of a portion of the top section 622 of the main fluid chamber 210 in accordance with various embodiments. Like features are labeled with the same reference numbers, such as the top section 622 of the main fluid chamber 210, first plate 303, second plate 304, fins/pins 412, threaded fins/pins 413, and threaded protrusions 414. The main fluid chamber 210 of FIG. 6 may provide another embodiment of the first threaded fins/pins 413E and the second threaded fins/pins 413F that extend approximately half of the width of the main fluid chamber 210. The first threaded fins/pins 413E and the second threaded fins/pins 413F may be bored and threaded before piercing through inner walls of the first threaded pins 413E and the second threaded fins/pins 413F and may be aligned so that the devices 212 can be mounted on the first plate 303C and the second plate 304C directly opposite from each other.

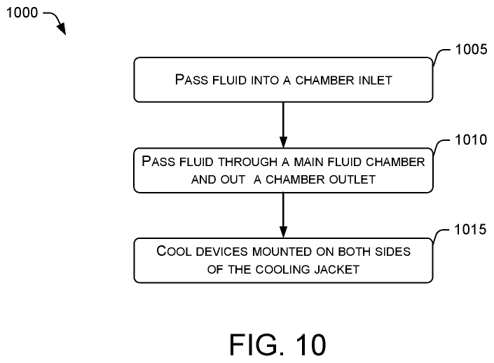

FIG. 10 is an illustration of a flow diagram illustrating an exemplary process 1000 for using the exemplary embodiments of the cooling jacket 120 shown in the preceding figures. At block 1005, fluid is passed into an inlet 206 (FIG. 2) of a main fluid chamber 210 (FIG. 2) that is positioned at or near a bottom wall 322 (FIG. 3) of a body structure 302 (FIG. 3). A portion (e.g., first half) of the width 702 (FIG. 7) of the main fluid chamber 210 may be positioned at a first plate 303 (FIG. 3), and the remaining portion (e.g., second half) of the width 702 of the main fluid chamber 210 may be positioned at a second plate 304 (FIG. 3). The first plate 303 may include first pins 412A, 412C, 412E (FIGS. 7-9) that the fluid flows around in the main fluid chamber, and first threaded pins 413A, 413C, 413E that may be bored and threaded so that devices 212 (FIG. 2) can be mounted on the first plate by way of threaded fasteners and the first threaded pins 413A, 413C, 413E.

The second plate 304 may include second pins 412B, 412D, 412F (FIGS. 7-9) that the fluid flows around in the main fluid chamber, and second threaded pins 413F (FIG. 9) that are bored and threaded so that the devices 212 can be mounted on the second plate by way of the threaded fasteners and the second threaded pins F (FIG. 9). At block 1010, the fluid is passed through the main fluid chamber 210 and out an outlet 216 (FIG. 2) that is positioned at or near the bottom wall of 322 the body structure 302. At block 1015, the devices 212 that are mounted on the first plate 303 and the second plate 304 are cooled as the fluid passes through the main fluid chamber 210.

While embodiments have been illustrated and described above, many changes can be made without departing from the spirit and scope of the disclosure. Accordingly, the scopes of the embodiments are not limited by the disclosure. Instead, the embodiments of the disclosure should be determined entirely by reference to the claims that follow.

What is claimed is:

1. A fluid transfer system, comprising:
a dual-sided cooling jacket having:
a main fluid chamber that receives and outputs fluid;
a first plate comprising:
first pins that extend into the main fluid chamber so that the fluid flows around the first pins in the main fluid chamber, and
first threaded pins that extend into the main fluid chamber, the first threaded pins being bored and threaded so that one or more devices can be mounted on a first outer surface of the first plate by way of threaded fasteners and the first threaded pins; and
a second plate joined to the first plate, the main fluid chamber formed between the first plate and the second plate, the second plate comprising:
second pins that extend into the main fluid chamber so that the fluid flows around the second pins in the main fluid chamber, and
second threaded pins that extend into the main fluid chamber, the second threaded pins being are bored and threaded so that the one or more devices can be mounted on a second outer surface of the second plate by way of the threaded fasteners and the second threaded pins.

2. The fluid transfer system of claim 1, further comprising:
a siphon line located in the dual-sided cooling jacket, the siphon line comprising a priming inlet that is fluidly connected to a siphon outlet, the siphon outlet being fluidly connected to the main fluid chamber at or near an outlet of the main fluid chamber,
wherein the priming inlet is configured to draw air bubbles out of the main fluid chamber and output the air bubbles at the siphon outlet.

3. The fluid transfer system of claim 1, wherein the first threaded pins are bored and threaded before piercing through an inner wall of the first threaded pins.

4. The fluid transfer system of claim 3, wherein the first threaded pins and the second pins are aligned.

5. The fluid transfer system of claim 3, wherein the second threaded pins are bored and threaded before piercing through an inner wall of the first threaded pins.

6. The fluid transfer system of claim 5, wherein the second threaded pins and the first pins are aligned.

7. The fluid transfer system of claim 1, wherein the first threaded pins and the second threaded pins are staggered so that the one or more devices that are mounted on the first plate and the second plate are misaligned from each other.

8. The fluid transfer system of claim 1, wherein the first threaded pins extend a width of the main fluid chamber, and wherein the second threaded pins extend the width of the main fluid chamber.

9. The fluid transfer system of claim 1, wherein the main fluid chamber comprises a top section and a bottom section, wherein a cumulative quantity of the first pins and the second pins located in the top section of the main fluid chamber is greater than a cumulative quantity of the first pins and the second pins located in the bottom section of the main fluid chamber.

10. A dual-sided cooling jacket configured to receive and cool devices on two sides of the cooling jacket, the cooling jacket comprising:
a body structure comprising a first plate joined to a second plate, the body structure having a top wall, a bottom wall, a right wall, and a left wall, a first exterior surface for mounting devices to be cooled, and a second exterior surface for mounting devices to be cooled; and
a main fluid chamber located within the body structure and between the first plate and the second plate,
wherein the first plate comprises:
the first exterior surface for mounting devices to be cooled;
a plurality of first pins extending into the main fluid chamber; and
a plurality of first threaded members that allow the devices to be cooled to be mounted to the first plate using threaded fasteners, and
wherein the second plate comprises:
the second exterior surface for mounting devices to be cooled;
a plurality of second pins extending into the main fluid chamber; and
a plurality of second threaded members that allow the devices to be cooled to be mounted to the second plate using threaded fasteners.

11. The dual-sided cooling jacket of claim 10, wherein the main fluid chamber comprises:
an inlet;
an outlet;
a left section that is positioned at or near the left wall and is fluidly connected to the inlet;
a top section that is positioned at or near the top wall and is fluidly connected to the left section;
a right section that is positioned at or near the right wall and is fluidly connected to the top section; and
a bottom section that is positioned at or near the bottom wall and is fluidly connected to the right section and to the outlet.

12. The dual-sided cooling jacket of claim 11, further comprising a siphon line extending from a priming inlet to a siphon outlet, the priming inlet fluidly connected to the right section of the main fluid chamber, the siphon outlet fluidly connected to the bottom section of the main fluid chamber, wherein the siphon line has a smaller minimum cross-sectional area than the main fluid chamber.

13. The dual-sided cooling jacket of claim 12, wherein a right section of the siphon line is located between the main fluid chamber and the right wall, and a bottom section of the siphon line is located between the main fluid chamber and the bottom wall.

14. The dual-sided cooling jacket of claim 10, wherein the first threaded members are threaded pins that are bored and threaded before piercing through an inner wall of the first threaded pins, and wherein the second threaded members are threaded pins that are bored and threaded before piercing through an inner wall of the second threaded pins.

15. The dual-sided cooling jacket of claim 10, wherein the main fluid chamber has a top section and a bottom section, wherein a quantity of the plurality of first pins in the top section is greater than a quantity of the plurality of first pins in the bottom section.

16. The dual-sided cooling jacket of claim 10, wherein the main fluid chamber has a top section and a bottom section, wherein a quantity of the plurality of second pins in the top section is greater than a quantity of the plurality of second pins in the bottom section.

17. The dual-sided cooling jacket of claim 10, wherein the second threaded pins are bored and threaded before piercing through an inner wall of the first threaded pins, and wherein the first threaded pins and the second threaded pins are aligned so that the one or more devices are mounted on the first plate and the second plate directly opposite from each other.

18. The dual-sided cooling jacket of claim 10, wherein the first threaded members and the second threaded members are staggered so that the one or more devices are mounted on the first plate and the second plate opposite and misaligned from each other.

19. The dual-sided cooling jacket of claim 10, wherein the first threaded members extend a width of the main fluid chamber, and wherein the second threaded members extend the width of the main fluid chamber.

20. A method of using a cooling jacket, comprising the steps of:
passing fluid into a chamber inlet of a main fluid chamber, wherein approximately a first half of the width of the main fluid chamber is positioned at a first plate and approximately a second half of the width of the main fluid chamber is positioned at a second plate, wherein the first plate includes:
first pins that the fluid flows around in the main fluid chamber, and
first threaded pins that are bored and threaded so that one or more devices are mounted on the first plate by way of threaded fasteners and the first threaded pins;
wherein the second plate includes:
second pins that the fluid flows around in the main fluid chamber, and
second threaded pins that are bored and threaded so that the one or more devices are mounted on the second plate by way of the threaded fasteners and the second threaded pins;
passing the fluid through the main fluid chamber and out a chamber outlet; and
cooling the one or more devices that are mounted on the first plate and the second plate.
